(19) United States
(12) Patent Application Publication
(10) Pub. No.: US 2007/0080388 A1
(43) Pub. Date: Apr. 12, 2007

(54) Capacitor assembly

(76) Inventor: Daisuke Inomata, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/543,782

(22) Filed: Oct. 6, 2006

(30) Foreign Application Priority Data
Oct. 11, 2005 (JP) 2005-296165

(51) Int. Cl. H01L 29/94

(52) U.S. Cl. 257/306

(57) ABSTRACT

A capacitor assembly includes a semiconductor substrate having an interlayer insulation film on a first main surface of the semiconductor substrate, and a conductive barrier layer formed on the interlayer insulation film. The capacitor assembly also includes a contact plug electrically connected to the conductive barrier layer through the interlayer insulation film, and a lower electrode formed on the barrier layer. The capacitor assembly also includes a capacitor insulation film formed on the lower electrode, and an upper electrode formed on the capacitor insulation film. The capacitor insulation film is made from a ferroelectric material. The barrier layer is an amorphous film which includes titanium and aluminum.

### BACKGROUND OF THE INVENTION

1. Field of the Invention

The present invention relates to a capacitor assembly which includes a ferroelectric metal oxide as a capacitor insulation film and is usable for a capacitor part of a ferroelectric memory.

2. Description of the Related Art

Lead zirconium titanate (Pb(Zr₁₋ₓTiₓ)O₃) (called ‘PZT’ hereinbelow), strontium barium titanate (Ba₁₋ₓSrₓTiO₃) (called ‘BST’ hereinbelow), and strontium bismuth niobate tantalate (SrBi₂(Nb₁₋ₓTaₓ)₂O₉) (called ‘SBT’ hereinbelow) are used as ferroelectric materials of capacitor insulation films in a capacitor assembly. Here, x represents a composition ratio in a rage from 0 to 1.

The capacitor assembly generally includes the capacitor insulation film which is made of a ferroelectric material, an upper electrode which is formed on the capacitor insulation film, and a lower electrode which is formed under the capacitor insulation film. The capacitor assembly also includes a conductive barrier layer which is formed under the lower electrode, and an interlayer insulation film formed under the barrier layer. The interlayer insulation film is formed over an entire first main surface of a semiconductor substrate. A contact plug which is electrically connected to the conductive barrier layer penetrates through the interlayer insulation film.

Oxygen diffusion from the capacitor insulation film is one of the problems of the conventional capacitor assembly. Because of a heat treatment which is carried out when sintering the capacitor insulation film, oxygen diffuses from the capacitor insulation film through the lower electrode and the conductive barrier layer, and oxidizes a surface of the contact plug which is made of tungsten (W). As a result, conductivity of the contact plug is spoiled.

The problem of oxidation of the contact plug surface is particularly serious when the contact plug is formed by a chemical mechanical polishing (called ‘CMP’ hereinbelow) method.

When the contact plug is formed by the CMP method, a difference in the polishing speed between the contact plug and the interlayer insulation film creates a step of 20 nm to 50 nm at (along) the interface between the contact plug and interlayer insulation film. As a result, a significant separation (called ‘seam’ hereinbelow) is created in the lower electrode and the conductive barrier layer.

Consequently, oxygen easily diffuses up to the contact plug through the seam, and oxidizes the contact plug surface.

To prevent the oxygen diffusion, various approaches have been proposed. One approach is use of a layered film structure which includes platinum (Pt), IrO₂ and iridium (Ir), as the lower electrode. Oxygen which diffuses through the platinum film and IrO₂ film is consumed by oxidation of the iridium film, and the diffusing oxygen is trapped in the iridium film. Accordingly, the diffusion of oxygen to the contact plug is prevented.

Japanese Patent Kokai No. H8-64786 discloses a conductive barrier layer provided between the lower electrode and the contact plug in order to prevent oxygen diffusion to the contact plug surface. This barrier layer includes an electrically conductive TiAlN film made of a crystal material containing titanium, aluminum and nitrogen.

These approaches can prevent oxygen diffusion to the contact plug to a certain extent, but are not enough. This is because each of the IrO₂film, the iridium film, and the TiAlN film is crystal, and the seam exists (extends) in a perpendicular direction to the main surface of the semiconductor substrate. Oxygen diffuses through the seam because the seam serves as a diffusion passage. Accordingly, oxygen can oxidize the contact plug surface.

In order to suppress the oxygen diffusion through the seam, Japanese Patent Kokai No. 2005-150688 uses an amorphous TiAlN film as a conductive barrier layer. The amorphous TiAlN film does not have a particular orientation. This TiAlN film suppresses the orientation (directivity) of the lower electrode, which includes the iridium film and IrO₂ film, formed on the TiAlN film.

This approach suppresses the orientation of the iridium film and IrO₂ film. Specifically, crystal grains of the iridium film and IrO₂film are made smaller and condensed so that a length of the oxygen diffusion passage becomes longer. As the passage becomes longer, an amount of oxygen diffusion which reaches the contact plug is reduced.

Japanese Patent Kokai No. 2005-150688 focuses on improvements on film qualities of the iridium film and IrO₂ film, and simply teaches that the TiAlN film under these films should be amorphous.

### SUMMARY OF THE INVENTION

The inventor of the present invention analyzed the oxidation of the contact plug surface which is caused by oxygen diffusion. The inventor found that it is not the film qualities of the iridium and IrO₂films, but rather the film quality of the TiAlN film that influences oxygen diffusion. The TiAlN film is the conductive barrier layer.

Specifically, the inventor concluded that oxygen diffusion can be suppressed by the conductive barrier layer if the conductive barrier layer is an amorphous TiAlN film. This conclusion does not depend on qualities of films (iridium film and IrO₂film) deposited on the barrier layer and absence/existence of steps between the contact plug and the interlayer insulation layer.

Also the inventor of the present invention found that this amorphous TiAlN film can be deposited under a particular deposition condition.

Further, the inventor of the present invention found that the TiAl film which does not include nitrogen can also suppress the oxygen diffusion, similar to the above described amorphous TiAlN film.

One object of the present invention is to provide a method of depositing an amorphous film which includes titanium, aluminum, and nitrogen. Nitrogen is an optional component.

Another object of the present invention is to provide a capacitor assembly which can suppress oxygen diffusion.

Still another object of the present invention is to provide a method for fabricating such capacitor assembly.

According to one aspect of the present invention, there is provided a method of depositing an amorphous film which includes titanium, aluminum and nitrogen. Nitrogen is an optional component. A TiAl is used as a sputtering target. The electric resistance of the amorphous film is 6×10² μΩcm or less. The amorphous film is deposited on a semiconductor substrate under the following deposition conditions:
(1) A DC power supply during sputtering process is between 0.5 kW and 10 kW and preferably between 1 kW and 3 kW.
(2) An inner pressure of a vacuum chamber for film deposition is between 3 mTorr and 15 mTorr, and preferably between 6 mTorr and 12 mTorr.
(3) A temperature of the semiconductor substrate is between 100 degrees Celsius and 300 degrees Celsius.
(4) A volume ratio of a nitrogen gas in a N₂—Ar mixed sputtering gas is between 0% and 70%.

According to this amorphous film deposition method, the resulting amorphous TiAlN film includes nitrogen as an optical element, and has an electric resistance of 6×10² μΩcm or less. Because the TiAlN film is an amorphous film, seams do not exist inside the TiAlN film. Therefore, by applying the TiAlN film as a conductive barrier layer of a capacitor assembly, oxygen diffusion through the seam of the conductive barrier layer is prevented.

Especially, even if the seam exists inside a lower electrode, the seam cannot penetrate through the amorphous TiAlN film. Therefore, oxygen which diffuses through the seam is blocked by the amorphous TiAlN film.

The amorphous TiAlN film including nitrogen which is an optional element has an electric resistance smaller than that of a crystal TiAlN film, so that an electric resistance between a contact plug and the lower electrode becomes smaller than that of a conventional device.

Definitions of terms which are used in following description are shown in Table 1.

TABLE 1

| | | | | | Within the | | |
|---|---|---|---|---|---|---|---|
| | | Component | | | Scope of the | | General |
| No | Membrane | Titanium | Aluminum | Nitrogen | Invention | Name | Name |
| 1 | Amorphous | contained | contained | not | Yes | 1st phase | TiAlN |
| | | | | contained | | TiAlN film | film |
| 2 | | contained | contained | contained | | (amorphous | |
| | | | | | | film) | |
| 3 | Crystal | contained | contained | contained | No | 2d phase | |
| | | | | | | TiAlN film | |

As seen from Table 1, the present invention encompasses both an amorphous TiAlN alloy film (No. 1) which is formed from titanium and aluminum without nitrogen, and another amorphous TiAlN film (No. 2) which is formed from titanium, aluminum and nitrogen. In the following description, the No. 1 film and No. 2 film are called a first phase TiAlN film.

The present invention does not encompass a crystal TiAlN film (No. 3) which is formed with titanium, aluminum, and nitrogen. This No. 3 film is called a second phase TiAlN film.

In the following description, No. 1 film to No. 3 film are generally called TiAlN film.

In the present invention, the first phase TiAlN film, that is, the amorphous TiAlN film, has higher reproducability. By applying the amorphous TiAlN film as the conductive barrier layer of the capacitor assembly, oxidation of the contact plug surface which is caused by oxygen diffusion can be suppressed.

### BRIEF DESCRIPTION OF THE DRAWINGS

FIG. 1 is a cross-sectional view of a capacitor assembly.

FIG. 2 is a graph showing a relationship between an electric resistance and a volume ratio of nitrogen in a TiAlN film which is formed under six different deposition conditions.

FIG. 3A shows XRD analysis results for a first phase TiAlN film.

FIG. 3B shows XRD analysis results for a second phase TiAlN film.

FIG. 4A is an SEM photograph showing a cross-sectional view of the first phase TiAlN film.

FIG. 4B is an SEM photograph showing a cross-sectional view of the second phase TiAlN film.

FIG. 5 is a cross-sectional view of a conductive barrier layer of the capacitor assembly.

### DETAILED DESCRIPTION OF THE PRESENT INVENTION

Referring to the drawings, embodiments of the present invention are described below. Each of the drawings is prepared for easy understanding of the present invention about shapes, size and arrangement of elements of a capacitor assembly. Materials and numerical conditions used in the following description are only preferable examples. Therefore, the present invention should not be limited to the embodiments.

### FIRST EMBODIMENT

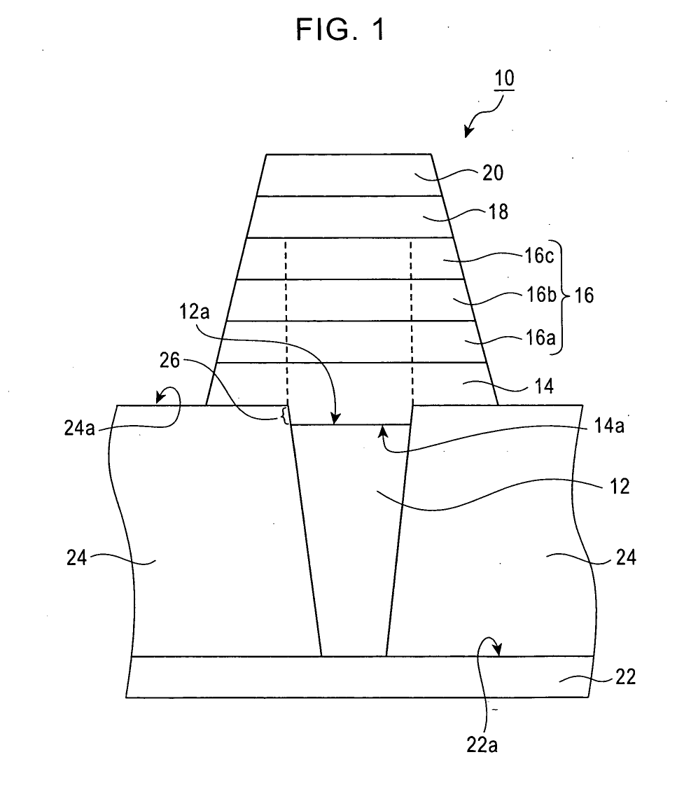

Referring to FIG. 1, a capacitor assembly 10 is described. A capacitor assembly 10 is formed on a main face 22a of a semiconductor substrate. A cross-sectional shape of the capacitor assembly 10 is generally trapezoid. The capacitor assembly 10 includes a contact plug 12, a conductive barrier layer 14, a lower electrode 16, a capacitor insulation film 18 and an upper electrode 20.

The contact plug 12 is formed through an interlayer insulation film 24 which is formed on the main surface 22a of the semiconductor substrate 22. An upper surface 12a of the contact plug 12 is electrically connected to a lower surface of the conductive barrier layer 14. A lower end of the contact plug 12 is electrically connected to a transistor (not shown), which is formed on the main surface 22a of the semiconductor substrate 22.

The interlayer insulation film 24 is, for example, an SiO₂ film. A thickness of the interlayer insulation film 24 is, for example, 800 nm. The contact plug 12 is, for example, formed with tungsten film by a chemical vapor deposition (called ‘CVD’ hereinbelow) method.

The contact plug 12 is formed by a following method. After formation of the interlayer insulation film 24, a contact hole is formed through the interlayer insulation film 24 by a known method. After filling the contact hall with tungsten and covering the interlayer insulation film 24 with a tungsten film, the tungsten film is polished to the surface of the interlayer insulation film 24 by a CMP method.

There is a step 26 which has 20 nm to 50 nm height between the contact plug 12 and the interlayer insulation film 24. In the lower electrode 16, a seam (not shown) extends along an extension line of the step 26 which is indicated by the vertical dashed line in FIG. 1.

The barrier layer 14 is electrically conductive and is formed on an upper surface 24a of the interlayer insulation film 24. A lower surface 14a of the barrier layer 14 is electrically connected to the contact plug 12. The barrier layer 14 includes a first phase TiAlN film, that is, an amorphous TiAlN film. A thickness of the barrier layer 14 is, for example, about 100 nm.

The lower electrode 16 includes an iridium film 16a, IrO₂ film 16b, and platinum electrode 16c, and is electrically connected to the barrier layer 14. The iridium film 16a, IrO₂ film 16b, and platinum electrode 16c are deposited on the barrier layer 14 in this order.

The iridium film 16a is made of an iridium metal and deposited by sputtering method. This iridium film 16a is crystal, and has the seam along a direction perpendicular to the main surface 22a of the semiconductor substrate. A thickness of the iridium film 16a is, for example, about 100 nm. The iridium film 16a functions as a sacrifice film. Specifically, the iridium film 16a itself is oxidized by oxygen which diffuses from the capacitor insulation film 18 through the platinum electrode 16c and IrO₂film 16b, so as to suppress oxygen diffusion to the barrier layer 14.

The IrO₂film 16b is made from oxidized iridium, and is deposited by a reactive sputtering method. The IrO₂ film 16b is crystal, and includes the seam along a direction perpendicular to the main surface 22a of the semiconductor substrate. A thickness of the IrO₂ film 16b is, for example, about 100 nm. The IrO₂ film 16b separates the platinum electrode 16c from the iridium film 16a spatially, and prevents a solution reaction which would be otherwise caused by direct contact between the iridium film 16a and platinum electrode 16c.

The platinum electrode 16c is made from metal platinum, and is deposited by a sputtering method. The platinum electrode 16c is crystal, and has the seam along a direction perpendicular to the main surface 22a of the semiconductor substrate. A thickness of the platinum electrode 16c is, for example, about 200 nm.

The capacitor insulation film 18 is formed on the lower electrode 16. The capacitor insulation film 18 is made from, for example, SBT, and is deposited by a known sol-gel process. A sintering temperature of the capacitor insulation film 18 is, for example, about 800 degrees Celsius. A thickness of the capacitor insulation film 18 is, for example, about 120 nm.

The upper electrode 20 is deposited on the capacitor insulation film 18. The upper electrode 20 is made from metal platinum, and is deposited by a sputtering method. A thickness of the upper electrode 20 is, for example, about 200 nm.

As described above, the semiconductor device 10 includes the conductive barrier layer 14 which is constituted by the first phase TiAlN film, i.e., the amorphous TiAlN film. Therefore, oxygen which diffuses from the capacitor insulation film 18 through the seam in the lower electrode is stopped by the barrier layer 14 which does not have seams. Accordingly, oxidation in and near the upper surface 12a of the contact plug 12 is avoided.

In this first embodiment, the thickness of the barrier layer 14 is about 100 nm. However, the barrier layer 14 may have other thickness if that thickness is enough to prevent or reduce oxygen diffusion. It is preferable that the barrier layer 14 has a thickness in a range of 20 nm to 150 nm. If the barrier layer 14 has a thickness of 20 nm or more, the barrier layer 14 can prevent or reduce the oxygen diffusion in a practically satisfactory level. It is more preferable that the barrier layer 14 has thickness of 50 nm or more. If the barrier layer 14 has a thickness of 50 nm or more, the barrier layer 14 prevents the oxygen diffusion in a more sufficient level. If the barrier layer 14 has a thickness of 150 nm or less, the barrier layer 14 prevents the oxygen diffusion in a sufficient manner on one hand and allows (ensures) easy etching on the other hand.

Assessment by the inventor of the present invention reveals that a deposition condition of the first phase TiAlN film does not depend on a type of the underlying layer (i.e., layer on which the TiAlN film is deposited). The deposition condition of the first phase TiAlN film does not relate to whether the underlying film is the interlayer insulation film 24 (SiO₂ film) or the Si substrate. In either case, the first phase TiAlN films can be obtained by the same deposition condition.

In this embodiment, SBT is used as the capacitor insulation film 18, but the material of the capacitor insulation film 18 is not limited to SBT. For instance, a ferroelectric oxide metal such as PZT and BST can be used for the capacitor insulation film 18.

### SECOND EMBODIMENT

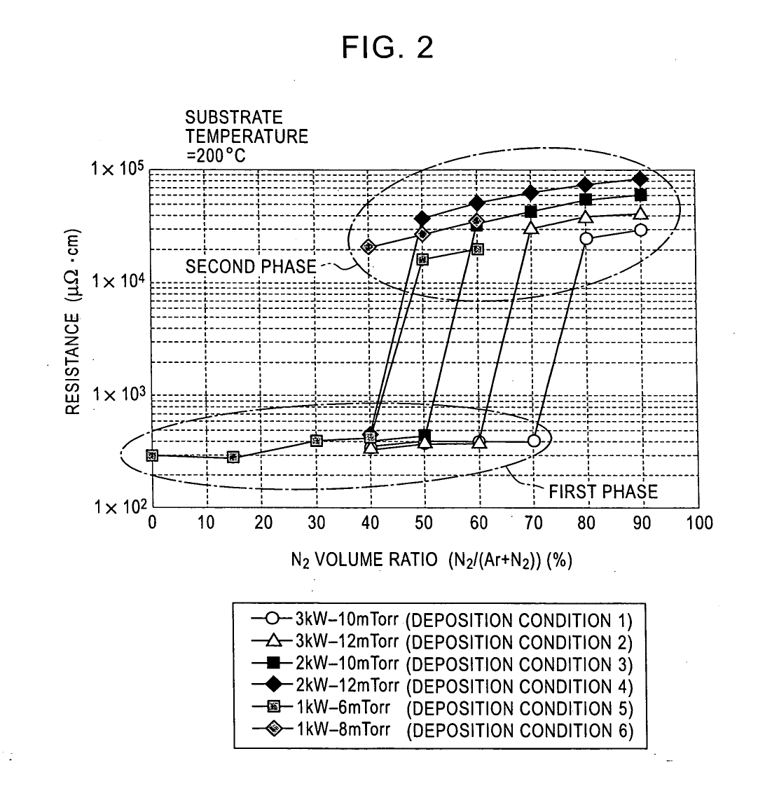

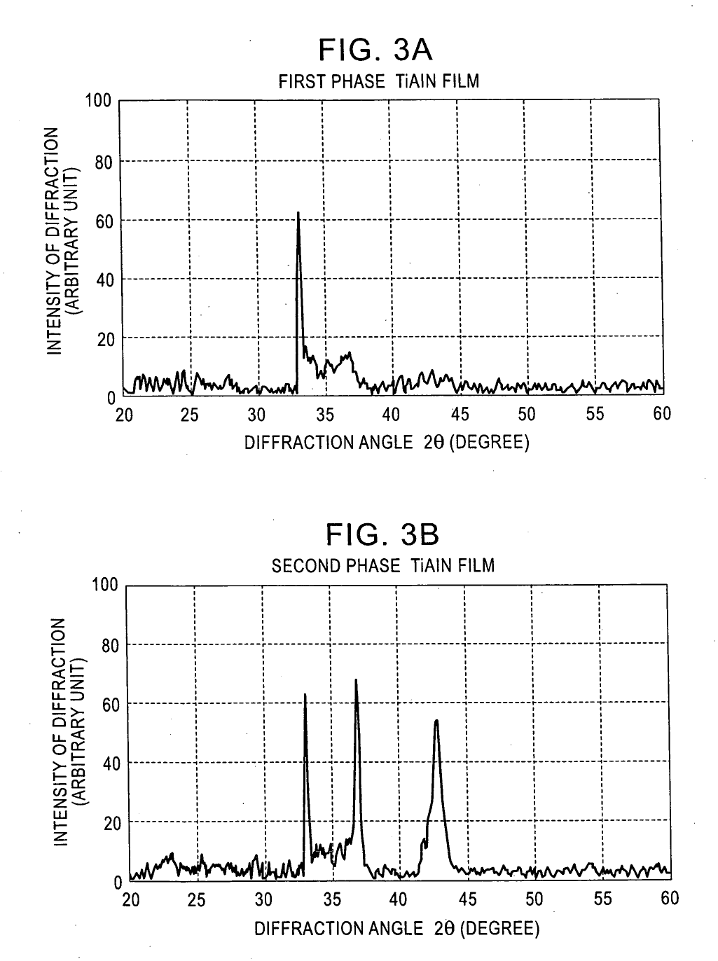

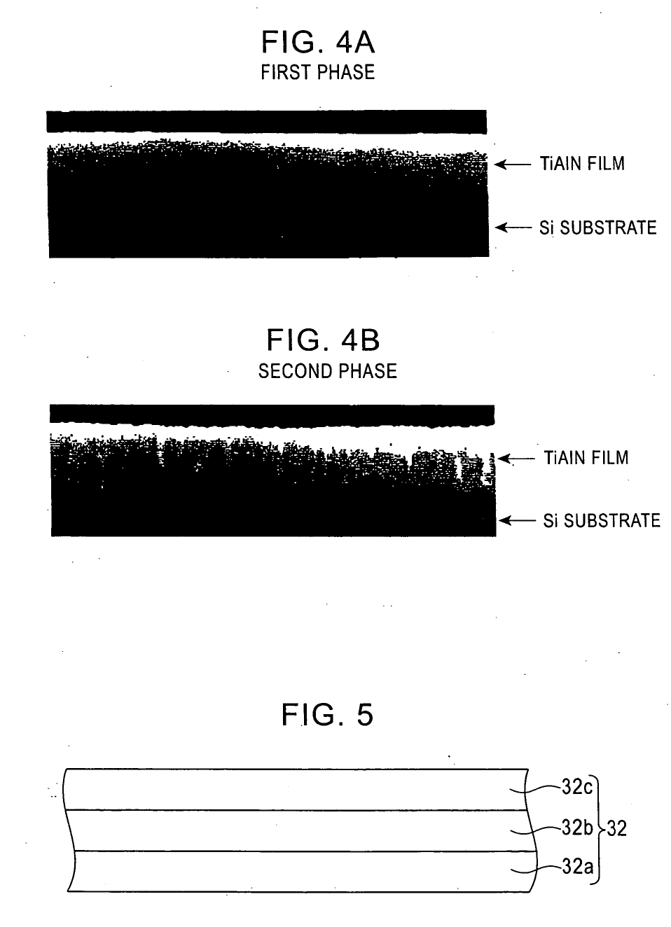

Referring to FIGS. 2, 3A, 3B, 4A and 4B, a method of depositing an amorphous film is described, and characteristics of a deposited amorphous film is also described. FIG. 2 is a graph showing the relationship between an electric resistance and a volume ratio of nitrogen in various TiAlN films which are deposited by six different fabrication methods. FIGS. 3A and 3B show XRD (X-ray diffractometer) analysis results of the first phase TiAlN film and second phase TiAlN film, respectively. FIGS. 4A and 4B are SEM (scanning electron microscope) photographs of the first phase TiAlN film and second phase TiAlN film, respectively.

Referring first to FIG. 2, the method of depositing the TiAlN film is described. In FIG. 2, the ordinate indicates an electric resistance (μΩcm) and the abscissa indicates a volume ratio of a nitrogen gas in a nitrogen-argon mixed sputtering gas (N₂/(N₂+Ar)) in percentage. A DC power (kW) and an inner pressure of a vacuum chamber for film deposition (mTorr) are also shown in FIG. 2.

Different TiAlN films shown in FIG. 2 are formed by simple sputtering methods (the nitrogen volume ratio=0%) or reactive sputtering methods (the nitrogen volume ratio>0%). A sputtering gas which has the nitrogen volume ratio as indicated by the abscissa of the graph of FIG. 2 is introduced into a vacuum chamber (film deposition chamber) of a film deposition device.

A substrate is used as an anode, and a sputtering target is used as a cathode. By applying a voltage across the anode and cathode, the sputtering gas is ionized (is plasmatized). In this embodiment, a TiAl target which includes aluminum and titanium in the ratio (atomic ratio) of 50:50 (i.e., Ti-50 atomic percent Al) is used as the sputtering target. A silicon plate is used as the substrate (the underlying film).

A positive ion in plasma is accelerated by an electric field across the substrate and the sputtering target, and collides with a surface of the sputtering target. By this collision, atoms of the sputtering target rush out of the sputtering target, and these atoms deposit on a surface of the substrate which faces the sputtering target.

When the volume ratio of nitrogen in the sputtering gas is lager than 0%, atoms which constitute the sputtering target react with nitrogen in the sputtering gas during the deposition process so that a TiAlN film which includes nitrogen is deposited on the substrate. The film deposition process proceeds with reaction sputtering.

On the other hand, when the volume ratio of nitrogen in the sputtering gas is 0%, a film deposition process proceeds with sputtering, and a TiAl film which does not include nitrogen is deposited on the substrate.

Generally, qualities of the deposition film on the substrate which is deposited by reactive sputtering depend on the following conditions (i) to (iv); (i) temperature of the substrate, (ii) DC power during sputtering process, (iii) pressure inside the film deposition chamber, and (iv) the volume ratio of nitrogen in the sputtering gas. The DC power is the product of the voltage applied to the sputtering target (i.e., cathode) and a current which flows through the sputtering target.

The deposition conditions (ii) to (iv) are changed for the six deposition films as shown in FIG. 2, with the deposition condition (i) being the same. The temperature of the substrate (condition (i)) is 200 degrees Celsius for all the six films. A TiAlN film which has an approximately 100 nm thickness is deposited on the substrate. The inventor found that the six deposition films (TiAlN films) are generally categorized into the following two types.

One type of TiAlN film is a first phase TiAlN film. The first phase TiAlN film has an electric resistance in a range of 2×10² μΩcm to 6×10² μΩcm. The other type of TiAlN film is a second phase TiAlN film, and has an electric resistance in a range of 1×10⁴ μΩcm to 1×10⁵ μΩcm. The first phase TiAlN film is one of films of the present invention. The first phase TiAlN film includes titanium, aluminum, and nitrogen. Nitrogen is an optional component. The first phase TiAiN has an electric resistance of 6×10² μΩcm or less.

The electric resistance of the first phase TiAlN film is obtained by multiplying a sheet resistance of the first phase TiAlN film by the thickness (100 nm) of the first phase TiAlN film. The sheet resistance is measured by a four-probe method.

The measurement of the electric resistance of the TiAlN film is performed without postprocessing (for example, heat treatment).

The inventor of the present invention performed XRD analysis and a cross-section SEM observation on the first and second phase TiAlN films respectively. Results of analysis and observations are shown in FIGS. 3A and 3B, FIGS. 4A and 4B.

FIGS. 3A and 3B show results of XRD analysis of the first and second phase TiAlN films respectively. The abscissa indicates a diffraction angel 2θ (degree), and the ordinate indicates an intensity of diffraction (arbitrary unit).

In the first phase TiAlN film, a peak is observed at a diffraction angel of 33 degrees, which is originated from a silicone substrate, as shown in FIG. 3A. The peak which is originated from the silicone substrate is only observed. This implies that the first phase TiAlN film is not crystal.

On the other hand, in FIG. 3B, peaks are observed at the diffraction angels of about 37 degrees and about 43 degrees which are originated from TiN, in addition to the peak which is originated from the silicon substrate observed in FIG. 3A.

FIGS. 4A and 4B are cross-section SEM photographs of the first and second phase TiAlN films, respectively. The SEM observation was performed at the magnification of 100,000 times.

As seen from FIG. 4A, a crystal grain is not observed in the first phase TiAlN film. As far as the observation is performed at this magnification, it can be said that the first phase TiAlN film does not have seams.

As seen from FIG. 4B, many post-like crystal grains which are orientated perpendicularly to the main surface of the substrate are observed in the second phase TiAlN film. The second phase TiAlN film includes many seams which extend in the film thickness direction.

As seen from FIGS. 3A, 3B, 4A, and 4B, it is found that the first phase TiAlN film is not crystal but amorphous. It is also found that the second phase TiAlN film is crystal.

Referring to FIG. 2 again, behavior of a transition from the first phase (amorphous) to the second phase (crystal) of the TiAlN film is described. A deposition condition (sputtering condition) to obtain the first phase TiAlN film, that is, the amorphous film of the present invention, is also described.

FIG. 2 shows the resistances of the TiAlN films which are deposited under the six deposition conditions #1 to #6 as shown in Table 2.

TABLE 2

| | DC power | Pressure Inside Deposition | Nitrogen Volume |
|---|---|---|---|
| | (kW) | Chamber (mTorr) | Ratio (%) |
| Deposition | 3 | 10 | 40 to 90 |
| Condition #1 | | | |
| Deposition | 3 | 12 | 40 to 90 |
| Condition #2 | | | |
| Deposition | 2 | 10 | 40 to 90 |
| Condition #3 | | | |
| Deposition | 2 | 12 | 40 to 90 |
| condition #4 | | | |
| Deposition | 1 | 6 | 0 to 60 |
| Condition #5 | | | |
| Deposition | 1 | 8 | 40 to 60 |
| Condition #6 | | | |

A temperature of a substrate is 200 degrees Celsius for all the deposition conditions #1 to #6.

A common change of behavior in TiAlN film quality, which appears in the deposition conditions #1 to #5, is described first.

As seen from FIG. 2, when the N₂ volume ratio is increased in each deposition condition, the resistance of the deposited film increases gradually in a range of 2×10² μΩcm to 6×10² μΩcm. TiAlN films which have the resistances in this range are the first phase TiAlN films.

It seems that the first phase TiAlN film is a TiAl alloy film (the nitrogen volume ratio=0%) which does not include nitrogen, or TiAl alloy film (nitrogen volume ratio>0%) which includes a relatively small quantity of nitrogen. It is assumed that quantities of titanium and aluminum are large comparing with the quantity of nitrogen in the first phase TiAlN film, and most of titanium and aluminum becomes alloy without coupling with nitrogen. Therefore, it is believed that the first phase TiAlN film keeps amorphous condition.

Also, it is assumed that a very small amount of TiN, which is hardly detected by the XRD analysis, is slightly generated in the first phase TiAlN alloy as the N₂ percentage increases. TiN is a conductive material, and the resistance of TiN is larger than that of the TiAl alloy (nitrogen volume ratio=0%). Therefore, it seems that the quantity of TiN increases with the increasing nitrogen volume ratio, and the resistance of first phase TiAlN film slightly increases correspondingly.

When the resistance of the TiAlN film enters a range of 4×10² μΩcm to 5×10² μΩcm with an additional increase of the nitrogen volume ratio, the resistance of the TiAlN film begins to increase steeply with the nitrogen volume ratio. A range of this steep increase of resistance is called a transition range.

In the transition range, when the nitrogen volume ratio increases about 10%, the resistance of the TiAlN film increases two digits.

This is probably because aluminum which keeps a metal state is nitrided rapidly in the transition range. It is believed that AlN is generated quickly in the transition range.

As is generally known, AlN is an electrically insulative material. It is believed, therefore, that as an occupation ratio of AlN become larger in the TiAlN film, the resistance of the TiAlN film steeply increases.

When the resistance of the TiAlN film becomes in a range of 1×10⁴ μΩcm to 4×10⁴ μΩcm with an additionally increasing nitrogen volume ratio, an increasing rate of the resistance of the TiAlN film becomes gentle. Then, the resistance of the TiAlN film becomes larger slightly in a range of 1×10⁴ μΩcm to 1×10⁵ μΩcm as the nitrogen volume ratio increases. The TiAlN films which have the resistances in this range are the second phase TiAlN films.

Since the resistance becomes larger in the second phase TiAlN alloy, it is assumed that AlN is newly generated in the second phase TiAlN alloy as the nitrogen volume ratio increases.

Since the resistance of the second phase TiAlN film is in the order of 1×10⁴ μΩcm, it is cannot be recognized from FIG. 2 that TiN which has an approximately 1/100 of the resistance of the TiAlN film is generated in the second phase TiAlN alloy. It is assumed, however, that TiN is generated in the second phase TiAlN alloy as the nitrogen volume ratio increases because a peak which is originated from TiN is observed in the XRD analysis as shown in FIG. 3B.

In the deposition condition #6, the second phase TiAlN film is only observed. The inventor thinks that this is because a changing range of the nitrogen volume ratio (40%-60%) in the deposition condition #6 is smaller than that of other deposition conditions. Therefore, the first phase TiAlN alloy is believed to exist when the nitrogen volume ratio is less than 40%, even under the deposition condition #6.

In the deposition conditions #1 to #4, the XRD analysis is not performed when the nitrogen volume ratio is less than 40%. It is assumed that the TiAlN film in this range has a tendency similar to the TiAlN film created under the deposition condition #5.

According to the analysis results obtained under the deposition conditions #1 to #5, the inventor found the following tendencies #1 and #2 with respect to the phase transition from the first phase to the second phase.

(Tendency #1): When there is no difference in the DC power among the deposition conditions, the TiAlN films keep the first phase over a larger nitrogen volume ratio range as the pressure inside the film deposition vacuum chamber becomes lower. It is hardly to transit from the first phase to the second phase.

(Tendency #2): When there is no difference in the pressure inside the film deposition chamber among the deposition conditions, the TiAlN films keep the first phase over a larger nitrogen volume ratio range as the DC power becomes larger. It is hardly to transit from the first phase to the second phase.

The inventor also carried out experiments with the substrate temperature being changed, and found the following tendency #3.

(Tendency #3): When there is no difference in the DC power and the film deposition chamber pressure among the deposition conditions, the TiAlN films keep the first phase over a larger nitrogen volume ratio range as the substrate temperature becomes higher. It is hardly to transit from the first phase to the second phase.

The inventor concluded that it is necessary to set the DC power larger, the vacuum chamber pressure lower, and the substrate temperature higher, in order to obtain the first phase amorphous TiAlN film over a larger range of nitrogen volume ratio.

From a viewpoint of obtaining the first phase amorphous TiAlN film over a larger nitrogen volume ratio range, the inventor ranks the deposition conditions #1 to #6 as follows. The deposition condition #1 is most preferable, the deposition condition #2 is ranked second, the deposition condition #3 is ranked third, the deposition condition #4 is ranked fourth, the deposition condition #5 is ranked fifth, and the deposition condition #6 is ranked sixth. It should be noted that the deposition condition #4 is roughly equal to the deposition condition #5.

Under the deposition condition #1, the first phase TiAlN film is obtained in the nitrogen volume ratio range of 0% to 70%.

Under the deposition condition #2, the first phase TiAlN film is obtained in the nitrogen volume ratio range of 0% to 60%.

Under the deposition condition #3, the first phase TiAlN film is obtained in the nitrogen volume ratio range of 0% to 50%.

Under the deposition conditions #4 and #5, the first phase TiAlN film is obtained in the nitrogen volume ratio range of 0% to 40%.

Under the deposition condition #6, it is assumed that the first phase TiAlN film is obtained if the nitrogen volume ratio range is less than 40%.

In each deposition condition shown in FIG. 2, the nitrogen volume ratio changes at 10% intervals. Therefore, each of the upper limit values of the nitrogen volume ratio (i.e., 40%, 50%, 60% and 70%) for creation of the first phase TiAlN film may contain an error of 10% at most. In other words, the true upper limit of the nitrogen volume ratio is between the indicated upper limit (inclusive) and the indicated upper limit +10% (not inclusive), with the electric resistance of the TiAlN film being 6×10² μΩcm or less. In the case of the deposition condition #1, for example, the true upper limit value of the nitrogen volume ratio exists in a range of 70% (inclusive) to 80% (not inclusive).

According to the inventor's assessment, the first phase TiAlN film can be obtained in the following conditions. The temperature of the substrate is kept in a range of 100 degrees Celsius to 300 degrees Celsius, a DC power is kept in a range of 0.5 kW to 10 kW, and the pressure inside the deposition chamber is kept in a range of 3 mTorr to 15 mTorr if the nitrogen volume ratio has an appropriate value.

The inventor assumes that the capability of oxygen diffusion prevention (oxygen barrier property) of the first phase TiAlN film is improved with an increasing amount of nitrogen contained in the TiAlN film. The inventor understands that the increase in the resistance of the first phase TiAlN film reflects the increase in TiN of the TiAlN film, i.e., reflects the increase in nitrogen contained in the TiAlN film. Therefore, from a view point of the oxygen barrier capability, it is preferable to deposit the TiAlN film under the deposition condition which causes the TiAlN film to have a relatively high resistance in a range of 4×10² μΩcm to 5×10² μΩcm and which does not cause the transition from the first phase to the second phase.

For example, in the case of the deposition condition #1, it is preferable to set the nitrogen volume ratio to about 70%, more specifically, an appropriate value from 70% (inclusive) to 80% (not inclusive), which does not cause the transition of the TiAlN film property from the first phase to the second phase. The higher the nitrogen volume ratio, the higher the oxygen barrier capability. In the case of the deposition condition #2, it is preferable to set the nitrogen volume ratio to about 60%, more specifically, an appropriate value from 60% (inclusive) to 70% (not inclusive) which does not cause the transition of the TiAlN film property from the first phase to the second phase. The higher the nitrogen volume ratio, the higher the oxygen barrier capability. In the case of the deposition condition #3, it is preferable to set the nitrogen volume ratio to about 50%, more specifically, an appropriate value from 50% (inclusive) to 60% (not inclusive) which does not cause the transition of the TiAlN film property from the first phase to the second phase. The higher the nitrogen volume ratio, the higher the oxygen barrier capability. In the case of the deposition conditions #4 and #5, it is preferable to set the nitrogen volume ratio to about 40%, more specifically, an appropriate value from 40% (inclusive) to 50% (not inclusive) which does not cause the transition of the TiAlN film property from the first phase to the second phase. The higher the nitrogen volume ratio, the higher the oxygen barrier capability.

The inventor of the present invention confirmed that the first phase TiAlN film is stable with respect to heat treatment. It was confirmed that the first phase TiAlN film kept the first phase up to about 800 degrees Celsius and did not change to the second phase. 800° C. is a sintering temperature of the capacitor insulation film 18.

The inventor found that even if an amorphous film which consists of titanium and aluminum (the nitrogen volume ratio is 0%) is heat-treated in a nitrogen atmosphere, an amorphous film (the nitrogen volume ratio>0%) which includes titanium, aluminum and nitrogen cannot be obtained. In the first phase TiAlN films, the amorphous film (the nitrogen volume ratio>0%) which is made of titanium, aluminum and nitrogen can be only deposited by reaction sputtering.

Thus, the first phase TiAlN film of this second embodiment does not have seams in the film when observed by SEM. Therefore, if this film is used as the conductive barrier layer of the capacitor assembly, oxygen does not go through the TiAlN film because there is no seam or oxygen diffusion path in the TiAlN film. As a result, oxidation of a surface of the contact plug which is formed under the conductive barrier layer can be suppressed.

Since the resistance of the first phase TiAlN film is smaller than that of the second phase TiAlN film, it is possible to reduce the resistance between the contact plug and a lower electrode, as compared with a conventional capacitor assembly.

### THIRD EMBODIMENT

Referring to FIG. 5, a capacitor assembly of a third embodiment of the present invention is described. FIG. 5 is a cross-sectional view of a conductive barrier layer 32 of the capacitor assembly of the third embodiment. The capacitor assembly of the third embodiment has the same structure as the capacitor assembly 10 of the first embodiment except that the conductive barrier layer 32 has a three-layer structure. Therefore, illustration of the entire structure of the capacitor assembly of the third embodiment is omitted, and a description of common structures with the semiconductor device 10 (first embodiment) is also omitted.

The barrier layer 32 of the capacitor assembly of the third embodiment includes a layered structure which has a lower layer 32a, a middle layer 32b, and an upper layer 32c. The lower layer 32a and upper layer 32c are the crystal TiAlN films which are the second phase TiAlN films. The middle layer 32b is the amorphous TiAlN film which is the first phase TiAlN film.

The barrier layer 32 has a sandwich structure which includes two second phase TiAlN films (i.e., lower layer 32a and upper layer 32c) and a single first phase TiAlN film (i.e., middle layer 32b) sandwiched between the two second phase TiAlN films.

The thickness of the lower layer 32a, middle layer 32b and upper layer 32c is, for example, about 50 nm, respectively.

A method of depositing the barrier layer 32 is described below.

At first, the lower layer 32a is deposited. The lower layer 32a is deposited by a reaction sputtering method. Similar to the second embodiment, a TiAl target which includes aluminum and titanium in the ratio (atomic ratio) of 50:50 is used as a sputtering target. The lower layer 32a is deposited under a deposition condition suited for creation of the second phase TiAlN film (see FIG. 2).

Specifically, in the case of the deposition condition #1, the deposition of TiAlN film is performed with the nitrogen volume ratio of 80% or more. In the case of the deposition condition #2, the deposition of TiAlN film is performed with the nitrogen volume ratio of 70% or more. In the case of the deposition condition #3, the deposition of TiAlN film is performed with the nitrogen volume ratio of 60% or more. In the case of the deposition conditions #4 and #5, the deposition of TiAlN film is performed with the nitrogen volume ratio of 50% or more. In the case of the deposition condition #6, the deposition of TiAlN film is performed with the nitrogen volume ratio of 40% or more.

When the thickness of the lower layer 32a becomes about 50 nm, the deposition process is temporarily stopped. Then, in order to deposit the middle layer 32b of the first phase TiAlN film, the condition of the sputtering process is changed. Specifically, one or more of the following changes are made: (A) increasing the DC power, (B) decreasing the pressure inside the film deposition vacuum chamber, (C) increasing the substrate temperature, and (D) decreasing the nitrogen volume ratio.

Suppose that the lower layer 32a is deposited under the deposition condition #4 (the nitrogen volume ratio is 50%). As seen from FIG. 2, to deposit the middle layer 32b which is the first phase TiAlN film, one or more of the following changes (i) to (iv) are made: (i) increasing the DC power from 2 kW to 3 kW (deposition condition #2), (ii) decreasing the pressure inside the film deposition vacuum chamber from 12 mTorr to 10 mTorr (deposition condition #3), (iii) increasing the substrate temperature from 200° C. to 300° C. (not shown), and (iv) decreasing the nitrogen volume ratio from 50% to 40%.

The middle layer 32b is deposited after changing the deposition condition in the above described manner. When the thickness of the middle layer 32b becomes about 50 nm, the deposition process is temporarily stopped again. Then, the sputtering condition is changed, i.e., the sputtering condition is returned to the deposition condition used for the lower layer 32a. The upper layer 32c having a 50-nm thickness is deposited under this deposition condition.

In the third embodiment, the middle layer 32b of the barrier layer 32 has good barrier capability against oxygen. The middle layer 32b, which is easy to solve with other metal films, is placed between the lower layer 32a and upper layer 32c which are more stable than the middle layer 32b. Thus, the middle layer 32b is prevented from contacting directly to the other metal films, so that the barrier layer 32 keeps a good interface to the other metal films, when compared with a barrier layer having only the first phase TiAlN film.

As described in the second embodiment, it can be said that the first phase (amorphous) TiAlN film is a TiAl alloy which has a shortage of nitrogen. Therefore, there are many non-reacted Al atoms and Ti atoms inside the first phase TiAlN film. When the first phase TiAlN film contacts other metal films (e.g., the contact plug 12 or iridium film 16a), it may solve with such metal films. When the solution reaction occurs, it may be difficult to keep the good interface condition between the first phase TiAlN film and other metal films.

On the other hand, in the second phase TiAlN film, aluminum atoms and titanium atoms are nitrogenized enough. Therefore, even if the second phase TiAlN film contacts other metal films, the solution does not occur. Thus, the second phase TiAlN film keeps the good interface condition between other metal films and itself.

In the third embodiment, the layered structure which has the single first phase TiAlN film (the middle layer 32b) sandwiched between the two second phase TiAlN films (the lower layer 32a and upper layer 32c) is used as the barrier layer 32. It should be noted that this layered structure can be used as wiring to electrically connect various elements of the semiconductor device.

In this case, since the resistance of the first phase TiAlN film is smaller than that of the second phase TiAlN film, a current tends to flow to the first phase TiAlN film in the entire layered structure. Thus, the current flows easily in the layered structure which piles up the first phase TiAlN film and second phase TiAlN films, when compared with a structure or wiring which is made of the second phase TiAlN film(s) only.

Since both of the first and second phase TiAlN films have a property of barrier against hydrogen, the above described layered structure can be used as wiring to be connected to the upper electrode 20. This layered structure prevents hydrogen diffusion from the upper electrode 20 to the capacitor insulation film 18 so that it is possible to prevent deterioration of the capacitor insulation film 18 by hydrogen.

When the layered structure is used as the wiring, it is not always necessary that the layered structure is a three-layer structure. If the second phase TiAlN film is provided between the first phase TiAlN film and other metal film such that there is no direct contact between the first phase TiAlN film and other metal film, the layered structure may be a two-layer structure.

In the layered structure, a film which prevents direct contact between the first phase TiAlN film and other metal film is not necessarily the second phase TiAlN film. For example, a TiN film and TaN film may be used.

In a series of conductive barrier layer deposition processes, the sputtering conditions are changed when the middle layer 32b is created after the lower layer 32a and when the upper layer 32c is created after the middle layer 32b. At the sputtering condition change, it is preferable to place a shutter between the sputtering target and the substrate until the surface condition of the sputtering target becomes stable. The shutter prevents deposition of sputtered atoms onto the substrate while the sputtering target surface is unstable. As a result, interfaces between the lower layer 32a and the middle layer 32b, and between the lower layer 32b and the upper layer 32c become clear.

This application is based on Japanese Patent Application No. 2005-296165 filed on Oct. 11, 2005, and the entire disclosure thereof is incorporated herein by reference.

What is claimed is:

1. A capacitor assembly comprising:
a semiconductor substrate having a first main surface;
an interlayer insulation film formed on the first main surface of the semiconductor substrate;
a conductive barrier layer formed on the interlayer insulation film, the conductive barrier layer including an amorphous film which contains titanium and aluminum;
a contact plug penetrating the interlayer insulation film and electrically connected to the conductive barrier layer;
a lower electrode formed on the conductive barrier layer;
a capacitor insulation film made of a ferroelectric material and formed on the lower electrode; and
an upper electrode formed on the capacitor insulation film.

2. The capacitor assembly according to claim 1, wherein the conductive barrier layer further contains nitride.

3. The capacitor assembly according to claim 1, wherein the conductive barrier layer further includes first and second crystal films to sandwich the amorphous film, and the first and second crystal films are made from titanium, aluminum and nitrogen.

4. The capacitor assembly according to claim 1, wherein the conductive barrier layer has a thickness in a range of 20 nm to 150 nm.

5. The capacitor assembly according to claim 1, wherein the conductive barrier layer has a resistance in a range of 2×10² μΩcm to 6×10² μΩcm.

6. The capacitor assembly according to claim 5, wherein the conductive barrier layer is formed on the interlayer insulation film by sputtering, using a TiAl as a sputtering target, under following deposition conditions:
(1) DC power during the sputtering is between 0.5 kW and 10 kW;
(2) An inner pressure of a film deposition chamber is between 3 mTorr and 15 mTorr;
(3) A temperature of the semiconductor substrate is between 100 degrees Celsius and 300 degrees Celsius; and
(4) A volume ratio of a nitrogen gas in a N₂—Ar mixed sputtering gas is between 0% and 70%.

7. The capacitor assembly according to claim 3, wherein the first crystal film is provided on the interlayer insulation film under a first deposition condition, the amorphous film is provided on the first crystal film under a second deposition condition different from the first deposition condition, and the second crystal film is provided on the amorphous film under the first deposition condition.

8. The capacitor assembly according to claim 6, wherein the DC power during the sputtering is between 1 kW and 3 kW, and the inner pressure of the film deposition chamber is between 6 mTorr and 12 mTorr.
